(19) United States
(12) Patent Application Publication
(10) Pub. No.: US 2004/0132230 A1
(43) Pub. Date: Jul. 8, 2004

(54) Ball grid array substrate and method for preparing the same

(76) Inventor: Dong-Hern Kim, Chungcheongbuk-do (KR)

Correspondence Address: GOTTLIEB RACKMAN & REISMAN PC, 270 MADISON AVENUE, 8TH FLOOR, NEW YORK, NY, 100160601

(21) Appl. No.: 10/738,945

(22) Filed: Dec. 16, 2003

(30) Foreign Application Priority Data
Dec. 23, 2002 (KR) 2002-82649

(51) Int. Cl. H01L 21/48

(52) U.S. Cl. 438/106

(57) ABSTRACT

Disclosed herein are a ball grid array substrate and a method for preparing the substrate. More particularly, the lead lines connected to metal pads for electroplating the metal pads are cut using a combination of a laser drilling process and an etch back process, thereby economically providing BGA substrates capable of realizing very highly dense integrated circuits.

### BACKGROUND OF THE INVENTION

1. Field of the Invention

The present invention relates to a ball grid array substrate and a method for preparing the substrate. More particularly, the present invention relates to a ball grid array substrate prepared by forming conductive protecting layers on metal pads by electroplating the metal pads through lead lines connected to the metal pads for the purpose of connecting to the corresponding external terminals, and cutting the lead lines connected to the metal pads in a simple manner using a combination of a laser drilling process and an etch back process, thereby realizing very highly dense integrated circuits, and a method for preparing the ball grid array substrate.

2. Description of the Related Art

Semiconductor packages are generally fabricated by forming semiconductor chips such as single devices and integrated circuits on which various electronic circuits and wirings are laminated, forming signal input/output terminals toward a main board using lead frames or printed circuit boards (PCBs), and molding the terminals and the chips using a molding means in order to protect the semiconductor chips against various external circumstances including dust, moisture, electrical loads, mechanical loads, etc. and optimize and maximize the electrical performance of the semiconductor chips.

With recently advanced integration techniques for semiconductor chips and compactness for electronic devices, lightness, thinness, compactness and high reliability are required for semiconductor packages. In addition, the demands for array type semiconductor packages, pin grid array (PGA) semiconductor packages, ball grid array (BGA) semiconductor packages (hereinafter, referred to as ‘BGA packages’) and the like using lead frames are steadily increasing.

The BGA packages were developed to satisfy the demand for highly integrated semiconductor chips and multi-pins, and are one kind of surface mount type (SMT) packages which have a plurality of conductive balls, e.g., solder balls, with a particular shape arranged at the base for mounting on main boards. As for the ball grid array, solder balls on a ball grid array substrate are electrically bonded to the corresponding conductive connecting patterns of a printed circuit board.

In a prior art method for preparing a ball grid array substrate, an electroplating process is individually carried out through respective lead lines formed in the corresponding metal pads to form conductive protecting layers on the metal pads, preferably to electroplate the metal pads with gold for the purpose of connecting to external terminals. However, this prior art method is limited in the individual electroplating through the respective lead lines formed in the metal pads, in light of the demands for high integration and compactness of integrated circuits. Recently, methods for electroplating the metal pads through one leader after connecting the respective lead lines, to which the metal pads were connected, to the leader, have been utilized. After the electroplating is completed, portions of the lead lines are cut in order to prevent short circuits. As a process for cutting the lead lines, that is, portions to be cut, an etch back process using an alkaline etching solution is commonly adopted.

FIG. 1 is a flow chart schematically showing the prior art method for preparing a ball grid array substrate, and FIGS. 3a to 3f are cross-sectional views sequentially showing respective steps of the prior art method for preparing a ball grid array substrate.

Referring first to FIG. 3a, a conductive layer (a thin copper film) is formed on a substrate 1. Next, a photoresist film or dry film layer is formed on the outermost layer of the substrate 1 on which the conductive layer is formed, followed by light exposure, development, copper etching and peeling of the dry film, to form patterned metal pads 2 and a lead line 3.

Referring to FIG. 3b, solder mask layers 4 are formed on the substrate 1 on which the metal pads 2 and the lead line 3 are formed, and then partially peeled the solder mask layers 4 formed on the metal pads 2 and the lead line 3 by light exposure and development to form a solder mask opening 5 on the lead line 3.

Referring to FIG. 3c, a dry film 6 is applied on the solder mask opening 5 formed on the lead line 3 so as to protect the lead line 3 exposed through the solder mask opening 5 and act as a resist against plating involved in a subsequent gold plating step. At this step, the dry film 6 should be applied up to an extended distance enough to cover the solder mask opening 5. The distance is extended up to 120 μm in both (left and right) directions 7 and 7′ on the solder mask layer 4. Since the dry film 6 may be applied more in a particular direction 7 or 7′, it is common to apply the dry film 6 with a deviation of about 100 μm in both left and right directions.

Referring to FIG. 3d, gold-plated layers 8 are formed on the exposed metal pads 2 by electroplating the metal pads 2 through the lead line 3 connected to the metal pads 2 to provide contact pads. At this step, the formation of the gold-plated layers 8 is commonly carried out by sequentially plating the metal pads 2 with nickel and gold.

Referring to FIGS. 3e and 3f, the dry film 6 is peeled to expose the lead line 3, and then the lead line 3 is cut by an etch back process using an alkaline etching solution to prevent short circuits, thereby preparing a ball grid array substrate.

As described above, in the prior art method for preparing a ball grid array substrate, since the thickness of the solder mask is relatively large (40 μm or more) and a scattering light is used to develop the solder mask 5, solder remnants, i.e., undercuts, may remain at the bottom of the solder mask opening 5. Accordingly, the width of the solder mask opening 5 formed on the lead line 3 must be at least about 250 μm. As described above, in the step for applying the dry film 6 to protect the lead line 3 against the gold plating, the dry film 6 should be applied up to an extended distance sufficient to cover the solder mask opening 5 formed on the lead line 3. The distance is extended up to 120 μm in both (left and right) directions 7 and 7′, totally 240 μm. In addition, since the dry film 6 may be applied more in a particular direction 7 or 7′, a deviation of about 100 μm in both left and right directions, totally 200 μm, is required. Accordingly, the entire region required for cutting the lead line located at a dense circuit region is at least 690 μm (250 μm+240 μm+200 μm). In conclusion, the prior art method is spatially limited in the realization of very highly dense integrated circuits.

### SUMMARY OF THE INVENTION

Thus, the present inventors have conducted intensive research to solve the above problems of the prior art method for preparing a ball grid array substrate, and as a result, discovered a novel method for preparing a ball grid array substrate in which conductive protecting layers are formed on metal pads by electroplating the metal pads through lead lines connected to the metal pads, solder mask layers formed on the lead lines connected to the metal pads are selectively removed by a combination of a laser drilling process and an etch back process to form solder mask openings, and the lead lines exposed through the solder mask openings are cut, thereby eliminating the need for dry film application and peeling steps, accurately cutting portions to be cut located at a dense circuit region in a simple manner without defects such as eccentricity or unetching, and thus realizing very highly dense integrated circuits.

Therefore, it is an object of the present invention to provide a method for preparing a ball grid array substrate which can economically realize very highly dense integrated circuits.

It is another object of the present invention to provide a ball grid array substrate prepared in accordance with said method which can realize very highly dense integrated circuits.

According to one aspect of the present invention, there is provided a method for preparing a ball grid array substrate, comprising the steps of: forming patterned lead lines and metal pads on a resin-based insulating substrate; forming solder mask layers on the insulating substrate on which the lead lines and the metal pads are formed; partially peeling the solder mask layers by light exposure and development to expose the metal pads; forming conductive protecting layers on the exposed metal pads by electroplating the metal pads through the lead lines connected to the metal pads to provide contact pads; partially removing the solder mask layers using a laser drilling process to form solder mask openings on the lead lines connected to the metal pads; and cutting the lead lines exposed through the solder mask openings using an etching back process.

According to another aspect of the present invention, there is provided a ball grid array substrate prepared in accordance with said method.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a flow chart schematically showing a prior art method for preparing a ball grid array substrate;

FIG. 2 is a flow chart schematically showing a method for preparing a ball grid array substrate according to the present invention;

FIGS. 3a to 3f are cross-sectional views sequentially showing respective steps of a prior art method for preparing a ball grid array substrate;

FIG. 4a is a cross-sectional view showing the state in which a patterned lead line and metal pads are formed on a resin-based insulating substrate, according to one embodiment of the present invention;

FIG. 4b is a cross-sectional view showing the state in which solder mask layers are formed on the substrate on which the lead line and the metal pads are formed, after which the solder mask layers are partially peeled by light exposure and development to expose the metal pads, according to one embodiment of the present invention;

FIG. 4c is a cross-sectional view showing the state in which conductive protecting layers are formed on the exposed metal pads to provide contact pads, according to one embodiment of the present invention;

FIG. 4d is a cross-sectional view showing the state in which the solder mask layers are partially removed using a laser drilling process to form a solder mask opening on the lead line, according to one embodiment of the present invention;

FIG. 4e is a cross-sectional view showing the state in which the lead line is cut using an etch back process, according to one embodiment of the present invention;

FIG. 5 is a photograph showing the state in which a portion to be cut at which the respective lead lines connected to the metal pads are intersected is accurately cut using an etch back process, according to one embodiment of the present invention;

FIG. 6 is a photograph showing the state in which eccentricity arises after cutting the lead lines using an etch back process; and

FIG. 7 is a photograph showing the state of unetched lead lines after cutting the lead lines using an etch back process.

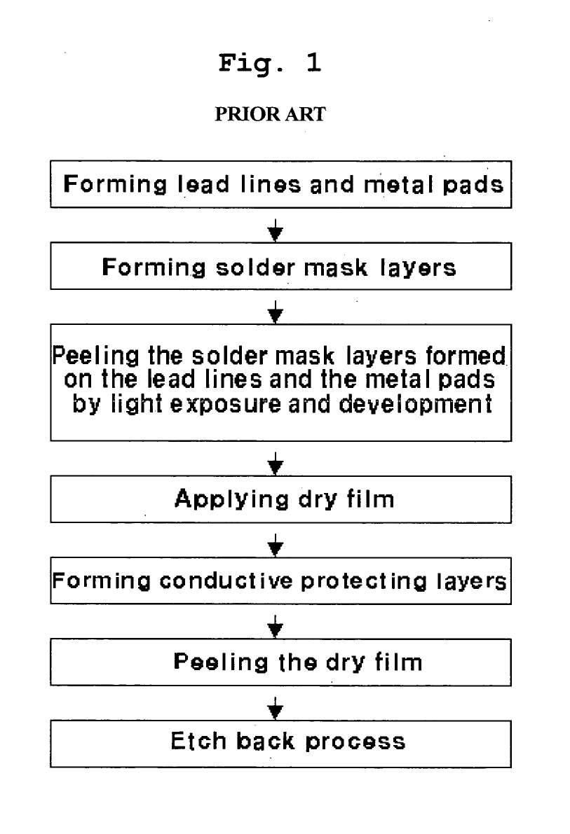

### DESCRIPTION OF THE PREFERRED EMBODIMENTS

Hereinafter, the present invention will be explained in more detail with reference to the accompanying drawings.

As discussed above, there are provided a method for preparing a ball grid array (BGA) substrate in which lead lines connected to metal pads are cut by a combination of a laser drilling process and an etch back process to electroplate the metal pads, thereby realizing very highly dense integrated circuits, and a BGA substrate prepared by said method.

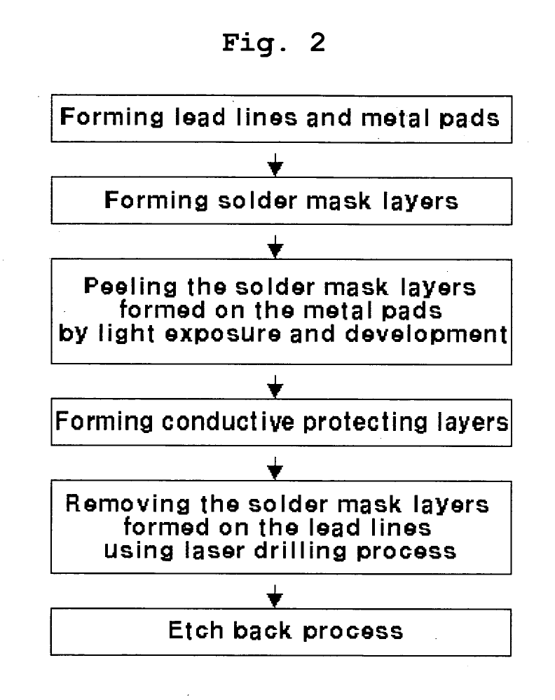

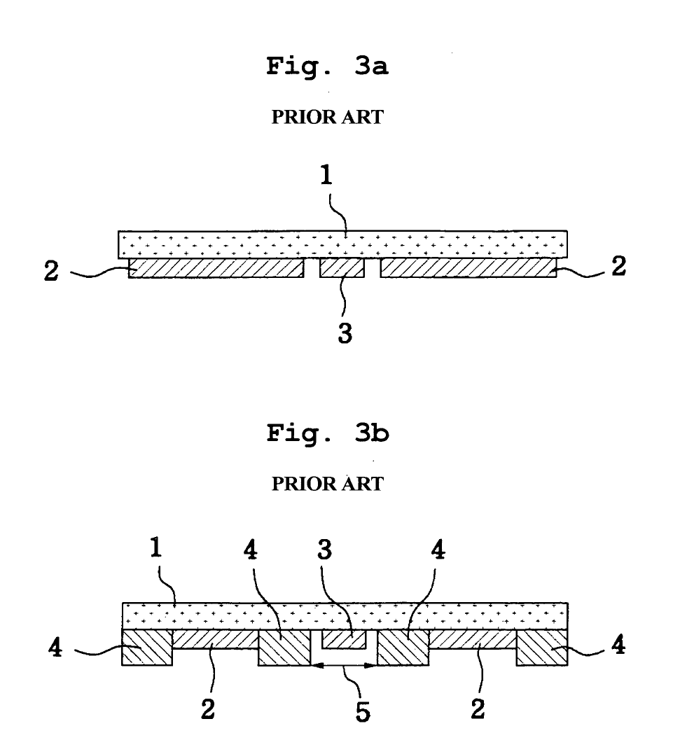

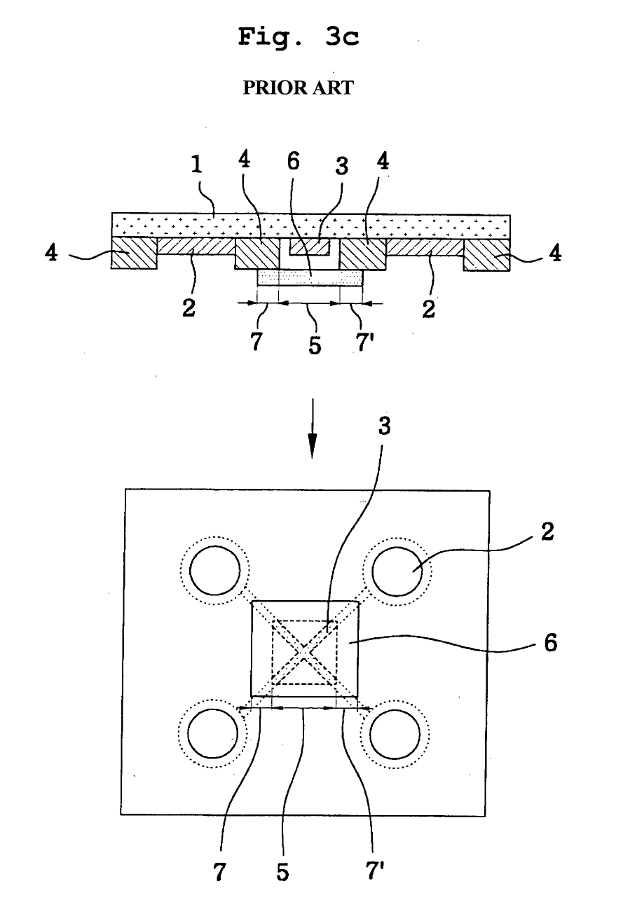

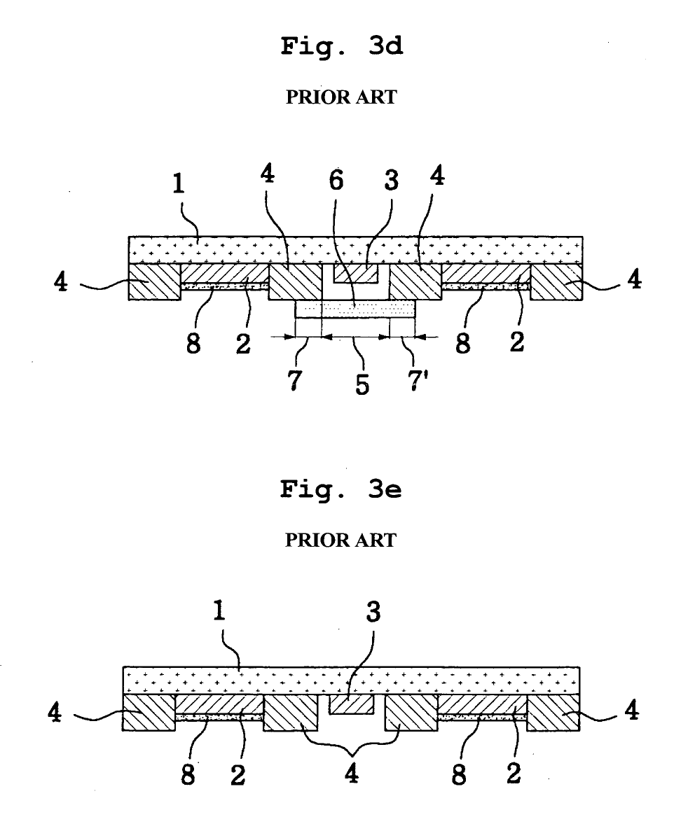

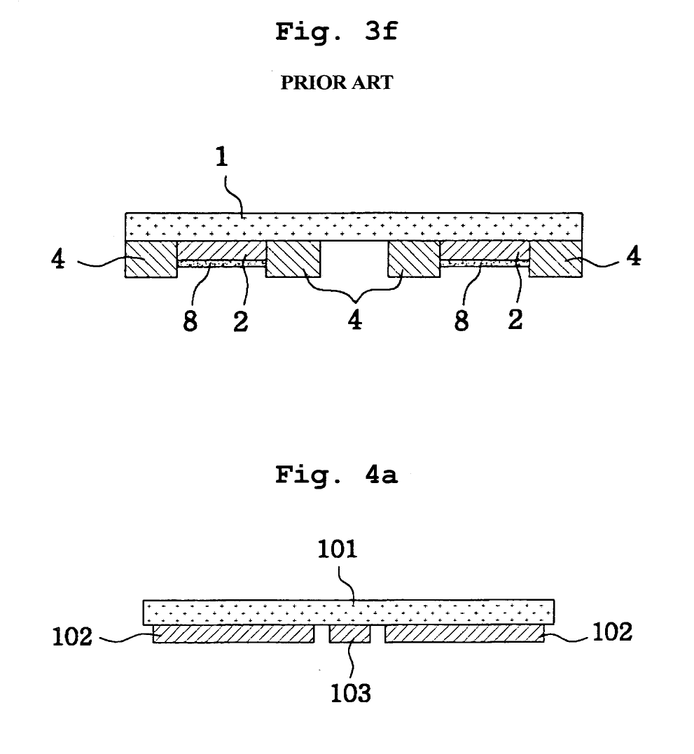

FIG. 2 is a flow chart schematically showing the method for preparing a ball grid array substrate according to the present invention.

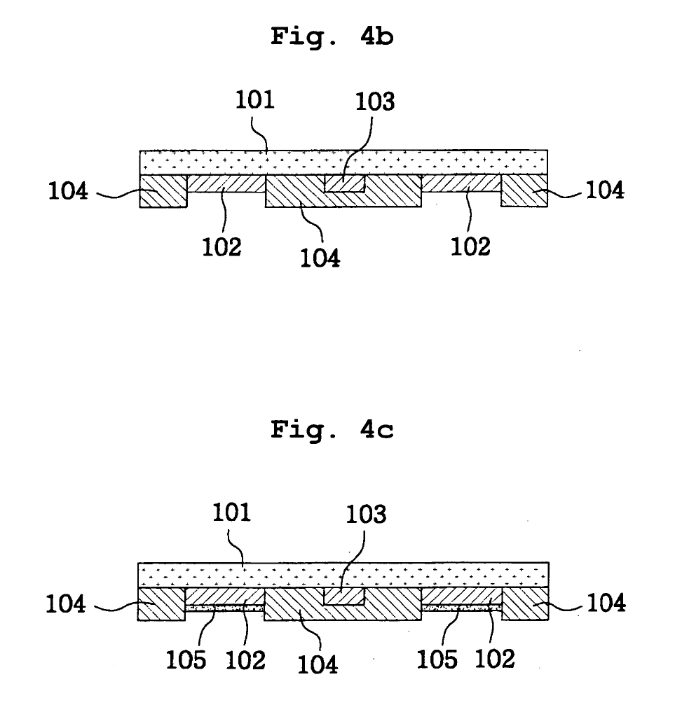

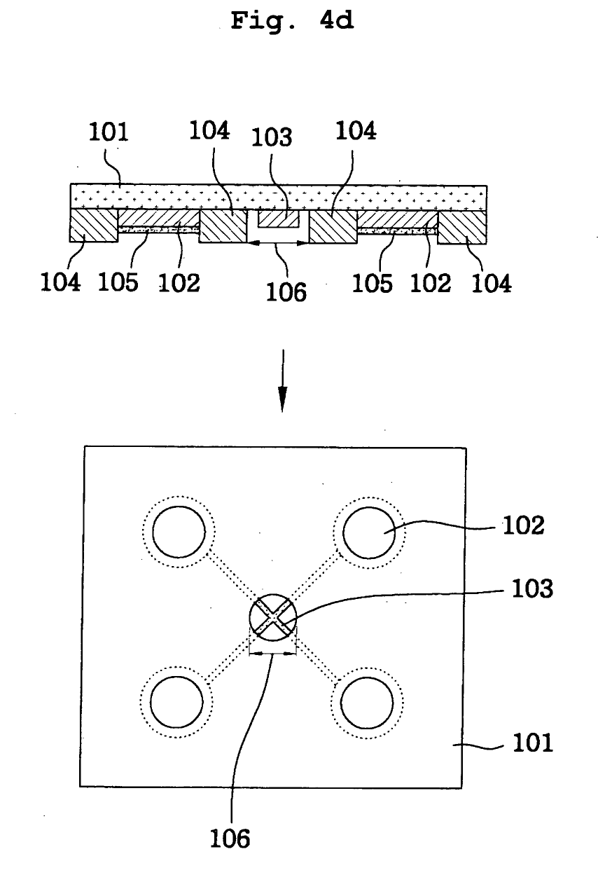

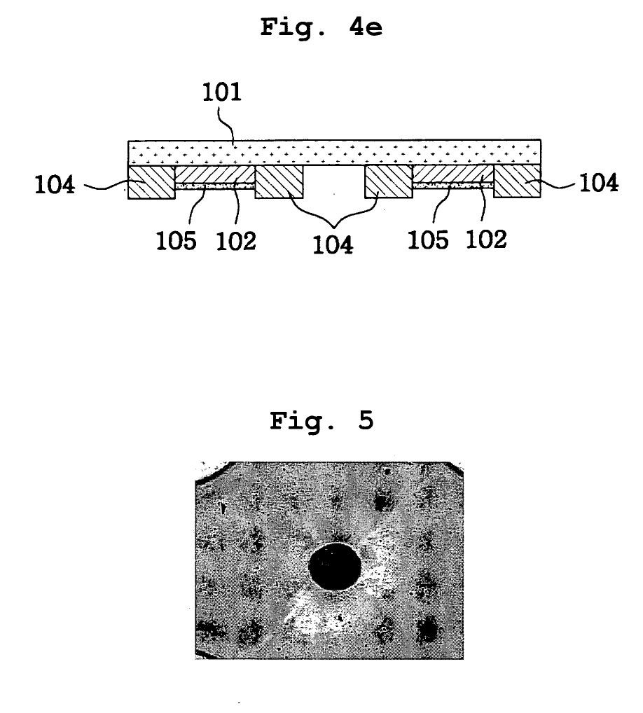

FIG. 4a is a cross-sectional view showing the state in which a patterned lead line and metal pads are formed on a resin-based insulating substrate, according to one embodiment of the present invention.

Referring first to FIG. 4a, patterned metal pads 102 and a lead line 103 are formed on a resin-based insulating substrate 101. At this step, a conductive metal layer, e.g., a bare copper layer, is formed on the substrate 101. The metal pads 102 and the lead line 103 can be formed using printed circuit board fabrication processes known in the art, particularly a photolithography process consisting of photosensitive resist/etching steps. A typical example of the processes for forming the metal pads 102 and the lead line 103 is carried out in accordance with the following procedure: After a metal layer is subjected to electroless plating on the substrate 101 to form a metal layer having a thickness of 15 μm or more, a dry film or photoresist is applied to the metal layer, followed by light exposure and development, to etch undesired portions of the metal layer. Thereafter, the remaining dry film as an etching resist is peeled to form patterned metal pads 102 and the lead line 103 on the outer layer of the substrate 101 together with a circuit pattern. The width of the lead line 103 is preferably within the range of 60˜80 μm. When the width of the lead line 103 pattern is less than 60 μm, there is a risk of short-circuiting due to defects such as eccentricity or unetching occurring during etching that will be described below. When the width of the lead line 103 is more than 80 μm, portions to be etched increase, which is not suitable for mass-production.

The substrate 101 used in the present invention has insulating properties, and may be an epoxy-glass consisting of a glass fiber and an epoxy resin coated thereon, polyimide, cyanate ester, bismaleimide-triazine (BT), polytetrafluoroethylene-based insulators, etc. Any insulator can be used so long as it is used as a substrate of printed circuit boards in the art.

FIG. 4b is a cross-sectional view showing the state in which solder mask layers are formed on the substrate on which the lead line and the metal pads are formed, after which the solder mask layers are partially peeled by light exposure and development to expose the metal pads, according to one embodiment of the present invention.

Referring to FIG. 4b, solder masks 104 are formed. The solder masks 104 protect the patterned metal layers 102 and 103, and act as a resist against plating involved in a subsequent step for forming conductive protecting layers. After the formation of the solder masks 104, the solder masks 104 covering the metal pads 102 are peeled by light exposure and development to expose the metal pads 102. The solder masks 104 applied on the substrate 101 and the metal layers 102 and 103 have a thickness of about 30˜45 μm enough to cover the substrate 101 and the metal layers 102 and 103. For the application, photo solder resist inks used in the art can be used.

Typical solder mask inks used in the art comprise an ether- or acetate-based compound as a solvent; a binder or matrix component consisting of an acid anhydride-modified epoxy acrylate (UV curable resin) and a cresol-novolac type epoxy resin or an isocyanurate epoxy resin (heat curable resin); an inorganic filler selected from barium sulfate, talc, silica, etc., and mixtures thereof; and a curing agent selected from at least difunctional acrylic monomers and dicyandiamide or melamine-based compounds. The solder mask inks may further comprise additives such as leveling agents, defoaming agents and dispersing agents, UV curable catalysts, pigments, etc. Any solder mask ink can be used so long as it is used as a solder resist or cover coating layer.

FIG. 4c is a cross-sectional view showing the state in which conductive protecting layers are formed on the exposed metal pads to provide contact pads, according to one embodiment of the present invention.

Referring to FIG. 4c, conductive protecting layers 105 are formed on the metal pads 102 by electroplating the metal pads 102 through the lead line 103 connected to the metal pads 102, to provide contact pads for connecting to external terminals. According to one embodiment of the present invention, the conductive protecting layers 105 can be formed on the metal pads 102 by individually electroplating the metal pads 102 through the respective lead lines 103 connected to the metal pads 102, in accordance with a process known in the art. According to another embodiment of the present invention, the conductive protecting layers 105 can be formed on the metal pads 102 by electroplating the metal pads 102 at one time through one leader after connecting the respective lead lines 103, to which the metal pads 102 were connected, to the leader. In addition, since it is difficult to directly plate the metal pads 102 with gold in order to form the conductive protecting layers 105 in view of the surface characteristics of the metal pads 102, it is preferred to subsequently plate the metal pads 102 with nickel and gold using an electroplating process. The nickel- and the gold-plated layers preferably have a thickness of about 3˜10 μm and 0.5˜1 μm, respectively.

FIG. 4d is a cross-sectional view showing the state in which the solder mask layers are partially removed using a laser drilling process to form a solder mask opening on the lead line, according to one embodiment of the present invention.

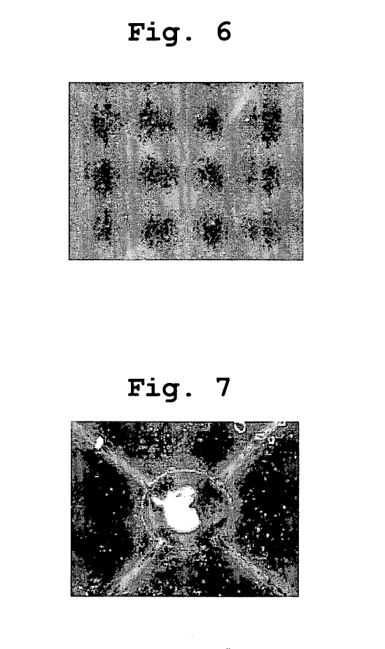

Referring to FIG. 4d, the solder mask layers 104 are partially removed using a laser drilling process to form a solder mask opening 106 on the lead line 103 connected to the metal pads 102. Meanwhile, the top view shown in FIG. 4d shows the state in which when electroplating the metal pads 102 at one time through one leader after connecting the respective lead lines 103, to which the metal pads 102 were connected, to the leader in accordance with one embodiment of the present invention, the solder mask opening 106 is formed on the lead line 103, that is, a portion to be cut at which the respective lead lines 103 connected to the metal pads 102 are intersected. The present invention is not limited to this embodiment. When individually electroplating the metal pads 102 through the respective lead lines 103 connected to the metal pads 102, the solder mask openings 106 may be formed on the respective lead lines 103 to open the lead lines 103. The width of the solder mask opening 106 is preferably within the range of 150˜250 μm, and more preferably 150˜200 μm. When the width of the solder mask opening is less than 150 μm, eccentricity may arise, as shown in FIG. 6. When the width of the solder mask opening is more than 250 μm, an unetched portion may be formed due to poor processability and delayed processing time, as shown in FIG. 7. Accordingly, when the width is out of this range, mass-production of the ball grid array substrate of the present invention is impossible and there is a disadvantage of low capability. On the other hand, the laser drilling process usable in the present invention is preferably Nd;YAG or CO₂ type laser process.

FIG. 4e is a cross-sectional view showing the state in which the lead line is cut using an etch back process, according to one embodiment of the present invention; and FIG. 5 is a photograph showing the state in which a portion to be cut at which the respective lead lines connected to the metal pads are intersected is accurately cut using an etch back process, according to one embodiment of the present invention.

Referring to FIGS. 4e and 5, the lead line 103 connected to the metal pads 102 for electroplating the metal pads 102 is cut using an etch back process, preferably a wet etch back process. The wet etch back process uses an alkaline etching solution for preventing short circuits. The lead line 103 exposed through the solder mask opening 106 is cut to prepare a BGA substrate.

On the other hand, the alkaline etching solution is obtained in accordance with the following reaction schemes:

Cu+Cu(NH₃)₄Cl₂→2Cu(NH₃)₂Cl

4Cu (NH₃)₂Cl+4NH₄OH+4NH₄Cl+O₂→4Cu (NH₃)₄Cl₂+6H₂O

Any etching solution can be used so long as it is used as an etching solution in an etch back process known in the art.

As described above, in accordance with the prior art method, a 690 μm or more wide region is needed in order to selectively cut lead lines located at a dense circuit region of a BGA substrate using an etch back process. In contrast, in accordance with the method of the present invention, a 150˜250 μm and preferably 150˜200 μm wide region is needed in order to selectively cut lead lines, that is, portions to be cut, located at a highly dense circuit region of a BGA substrate using a combination of a laser drilling process and an etch back process. Although the deviation (100 μm) in the left and right directions is considered, a 250˜300 μm wide region is needed. Accordingly, the present invention can be applied to substrates on which very highly dense integrated circuits are formed.

Further, when solder mask openings are formed on lead lines by light exposure and development in accordance with the prior art method, the solder mask openings cannot have a width of less than 250 μm in view of the operational characteristics of light exposure and development. In contrast, when solder mask openings are formed on lead lines by a laser drilling process in accordance with the method of the present invention, the solder mask openings can have a width of not more than 250 μm and preferably 150˜200 μm. Accordingly, the lead lines located at a highly dense circuit region can be selectively cut without any defects such as eccentricity and unetching, thereby economically preparing a BGA substrate capable of realizing very highly dense integrated circuits.

Furthermore, in accordance with the prior art method, the removal of solder masks is difficult due to poor development after curing the solder masks. The following procedure is carried out to facilitate the removal of the solder masks: first, solder masks covering lead lines to be cut are removed before forming conductive protecting layers on metal pads, to form solder mask openings. Next, a dry film is applied on the solder mask openings formed on the lead lines so as to act as a resist against plating involved in a subsequent gold plating step. After the gold plating, the dry film is peeled and then the lead lines are removed. This procedure requires considerably complex steps. In contrast, in accordance with the method of the present invention, since solder mask openings are formed by removing solder masks using a laser after curing the solder masks, conductive protecting layers can be formed on metal pads without the need for dry film application and peeling steps. After the formation of the conductive protecting layers, the solder mask openings are formed on lead lines to be cut using a laser. Accordingly, the lead lines can be cut in a simple manner.

The present invention will now be described in more detail with reference to the following Examples. However, these Examples are not to be construed as limiting the scope of the invention.

### EXAMPLE 1

An epoxy glass (CCL, Copper clad laminate) substrate having a size of 405 mm×510 mm was drilled and then subjected to an electroless plating process. The substrate was electroplated in a bath containing an electroplating solution at a current density of 2.0A/dm² at room temperature to form a copper layer having a thickness of about 15 μm thereon. A dry film was applied thereon, followed by light exposure and development, to etch undesired portions of the metal layer. The remaining dry film as an etching resist was peeled to form patterned copper pads and lead lines having a pattern width of about 60 μm, together with a circuit pattern.

Next, a solder mask layer was formed to a thickness of about 40 μm on the substrate on which the lead lines and the metal pads were formed, and then subjected to light exposure and development to peel the solder mask layer formed on the metal pads.

After connecting the respective lead lines, to which the metal pads were connected, to one leader, the metal pads were electroplated through the leader using a nickel-plating solution (nickel sulfamate) by applying a current to a nickel anode in accordance with a common electroplating process, to form a 5 μm thick nickel-plated layer. The nickel-plated layer was electroplated by applying a current to a platinum net in a gold plating bath containing a commercially available gold plating solution (soft gold plating) in accordance with a common electroplating process, to form a 0.5 μm thick gold-plated layer thereon.

The solder mask layer formed on the lead lines to which the leader was connected was removed in accordance with a common laser drilling process using CO₂ laser, to form 200 μm wide solder mask openings.

Finally, the lead lines were cut by a wet etching process using a common alkaline etching solution to prepare a high quality BGA substrate without any defects such as eccentricity or unetching.

### EXAMPLE 2

A high quality BGA substrate was prepared without any defects such as eccentricity or unetching in the same manner as in Example 1, except that the width of the solder mask openings formed on the lead lines to which the leader was connected was 230 μm.

As described above, according to the present invention, the conductive protecting layers are formed on the metal pads by electroplating the metal pads through the lead lines, connected to the metal pads for the purpose of connecting to the corresponding external terminals, and the lead lines connected to the metal pads are cut in a simple manner using a combination of a laser drilling process and an etch back process, thereby economically providing a BGA substrate on which very highly dense integrated circuits are formed.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for preparing a ball grid array substrate, comprising the steps of:
forming patterned lead lines and metal pads on a resin-based insulating substrate;
forming solder mask layers on the insulating substrate on which the lead lines and the metal pads are formed;
partially peeling the solder mask layers by light exposure and development to expose the metal pads;
forming conductive protecting layers on the exposed metal pads by electroplating the metal pads through the lead lines connected to the metal pads to provide contact pads;
partially removing the solder mask layers using a laser drilling process to form solder mask openings on the lead lines connected to the metal pads; and
cutting the lead lines exposed through the solder mask openings using an etching back process.

2. The method for preparing a ball grid array substrate according to claim 1, wherein the etch back process is a wet etch back process using an alkaline etching solution.

3. The method for preparing a ball grid array substrate according to claim 1, wherein the lead lines have a width of 60˜80 μm.

4. The method for preparing a ball grid array substrate according to claim 1, wherein the solder mask opening formed on the lead lines have a width of 150˜250 μm.

5. The method for preparing a ball grid array substrate according to claim 4, wherein the solder mask opening formed on the lead lines have a width of 150˜200 μm.

6. The method for preparing a ball grid array substrate according to claim 1, wherein the laser drilling process is Nd;YAG or CO₂ type laser drilling process.

7. The method for preparing a ball grid array substrate according to claim 1, wherein the conductive protecting layers are formed by individually electroplating the metal pads through the respective lead lines connected to the metal pads.

8. The method for preparing a ball grid array substrate according to claim 1, wherein the conductive protecting layers are formed by electroplating the metal pads at one time through one leader after connecting the respective lead lines, to which the metal pads were connected, to the leader.

9. The method for preparing a ball grid array substrate according to claim 8, wherein the solder mask openings are formed on portions at which the respective lead lines connected to the metal pads are intersected.

10. The method for preparing a ball grid array substrate according to claim 1, wherein the conductive protecting layers are double layers consisting of nickel- and the gold-plated layers.

11. The method for preparing a ball grid array substrate according to claim 1, wherein the solder mask layers have a thickness of 30˜45 μm.

12. The method for preparing a ball grid array substrate according to claim 10, wherein the nickel- and the gold-plated layers have a thickness of 3˜5 μm and 0.05˜μm, respectively.

13. A ball grid array substrate prepared by the method according to any one of claims 1 to 12.
